(19) United States
(12) Patent Application Publication
(10) Pub. No.: US 2020/0006714 A1
(43) Pub. Date: Jan. 2, 2020

(54) DISPLAY PANEL MOTHERBOARDS, DISPLAY PANELS, AND METHODS FOR MANUFACTURING DISPLAY PANEL

(71) Applicants: Yungu (Gu'an) Technology Co., Ltd., Langfang (CN); Kunshan Go-Visionox Opto-Electronics Co., Ltd., Kunshan (CN)

(72) Inventors: Li Zhang, Kunshan (CN); Ling Huang, Kunshan (CN); Minhui Xie, Kunshan (CN); Ping Zhou, Kunshan (CN); Murong Xue, Kunshan (CN)

(21) Appl. No.: 16/565,504

(22) Filed: Sep. 10, 2019

Related U.S. Application Data
(63) Continuation of application No. PCT/CN2019/071468, filed on Jan. 11, 2019.

(30) Foreign Application Priority Data
May 11, 2018 (CN) 201820706360.7
May 14, 2018 (CN) 201810455702.7

(51) Int. Cl. H01L 51/56; H01L 51/52

(52) U.S. Cl. CPC H01L 51/56; H01L 2251/566; H01L 51/5253; H01L 51/5246

(57) ABSTRACT

A display panel motherboard is provided. The display panel motherboard includes a plurality of display panels and a cutting reserved area, and at least a portion of the cutting reserved area is provided with a first reflective layer. The first reflective layer and a source/drain of the display panel are positioned on a same layer.

### CROSS REFERENCE TO RELATED APPLICATIONS

This disclosure is a continuation application of International Application PCT/CN2019/071468, filed on Jan. 11, 2019, which claims the priority benefits of Chinese Patent Application No. 201820706360.7, titled “DISPLAY PANEL MOTHERBOARD” and filed on May 11, 2018; and Chinese Patent Application No. 201810455702.7, titled “DISPLAY PANEL, METHOD FOR MANUFACTURING DISPLAY PANEL AND DISPLAY APPARATUS” and filed on May 14, 2018. The entireties of these applications are incorporated by reference herein for all purposes.

### TECHNICAL FIELD

The present disclosure relates to the field of display technologies.

### BACKGROUND

In recent years, with the development of technologies for smart terminal devices and wearable devices, the demand for display has become more diversified. For example, organic light emitting diode (OLED) displays possess auto luminescence, in which energy-consuming backlight modules are not used, thereby having energy-saving advantage compared with LCD panels.

### SUMMARY

It is necessary to provide a display panel motherboard with high encapsulation reliability, a display panel, a method for manufacturing display panel and a display device.

According to one aspect of the present disclosure, a display panel motherboard is provided, which includes a plurality of display panels and a cutting reserved area surrounding each of the display panels, at least a portion of the cutting reserved area being provided with a first a reflective layer, and the first reflective layer and a source/drain of the display panel are positioned on a same layer.

In the aforementioned display panel motherboard, at least a portion of the cutting reserved area is provided with a first reflective layer, and when cut into display panels, the first reflective layer can reflect laser energy, thereby functioning to amplify the laser energy. In an actual operation, the laser energy can be appropriately reduced, as well as the laser spot, and the laser is amplified by the first reflective layer to achieve the cutting requirement. In this way, the risk that moisture penetrating from the side of the display panel to cause poor encapsulating due to the damage to the film such as the encapsulating film because of thermal expansion is reduced, which improves encapsulation reliability and the yield rate and service life of the display panel.

In addition, the first reflective layer is disposed in the same layer as the source/drain in the thin film transistor (TFT) array substrate of the display panel. The first reflective layer and the source/drain of the display area can be synchronously formed without additional process, which is convenient in manufacturing.

In an exemplary embodiment, the cutting reserved area is at least located on one side of the display panel, and the first reflective layer is disposed in the cutting reserved area.

In an exemplary embodiment, the display panel further includes a binding area, the binding area is located on one side of the display panel, the cutting reserved area provided with the first reflective layer and the binding area are not located on the same side of the display panel.

In an exemplary embodiment, both of a side surface of the display panel without the binding area and the cutting reserved area are provided with the first reflective layer.

In an exemplary embodiment, the first reflective layer is a metal reflective layer or a metal alloy reflective layer.

In an exemplary embodiment, the first reflective layer has a multilayer structure.

In an exemplary embodiment, the first reflective layer is a Ti/Al/Ti laminates or a Mo/Al/Mo laminates.

In an exemplary embodiment, the display panel further includes an encapsulation area, the cutting reserved area surrounds the encapsulation area, and a second reflective layer is disposed in a non-display area of the encapsulation area.

In an exemplary embodiment, the first reflective layer and the second reflective layer are disposed on a same layer.

In an exemplary embodiment, both of the first reflective layer and the second reflective layer are metal reflective layers.

In an exemplary embodiment, the display panel includes a thin film encapsulation structure disposed on the display area and the encapsulation area, and the thin film encapsulation structure has a groove defined at an interval.

In an exemplary embodiment, the display area is provided with a pixel defining layer, a first dam and a second dam, the first dam and the second dam surround the pixel defining layer are disposed in the encapsulation area, and the thin film encapsulation structure includes at least two stacked inorganic encapsulation layers and an organic encapsulation layer disposed between two adjacent inorganic encapsulation layers. The inorganic encapsulation layer in the thin film encapsulation structure is disposed at an interval between the first dam and the second dam.

The present disclosure further provides a display panel formed by cutting the aforementioned display panel motherboard. The display panel includes: a display area; and an encapsulation area, the encapsulation area surrounding an outer circumference of the display area and having a second reflective layer disposed in the encapsulation area.

In an exemplary embodiment, the display panel further includes: a substrate, and a cover plate disposed opposite to the substrate. The encapsulation area is formed by an encapsulation layer, the encapsulation layer bonds the substrate and the cover plate, and the substrate, the encapsulation layer, and the cover plate enclose a sealed space disposing a display device. The encapsulation layer is provided with a groove, and the groove opening faces or faces away from the cover plate. The groove is filled with a solid heat absorbing material.

In an exemplary embodiment, the groove is opened on a surface of the encapsulation layer along an enclosing direction of the encapsulation layer.

In an exemplary embodiment, the encapsulation layer is annular, and the groove is disposed adjacent to an outer edge of the encapsulation layer.

In an exemplary embodiment, a thickness of the groove is less than a thickness of the encapsulation layer.

In an exemplary embodiment, a width of the groove is one-third to one-half of a width of the encapsulation layer.

In an exemplary embodiment, a section of the groove along a direction perpendicular to the cover plate is a curved surface.

The present disclosure further provides a method for manufacturing a display panel, which includes: providing a substrate, and dividing a display area and a encapsulation area on the substrate; coating a solid heat absorbing material at an edge of the encapsulation area; coating glass beads on the heat absorbing material, the glass beads covering the entire heat absorbing material; disposing a display device on the display area of the substrate, and bonding the substrate and a cover plate to form a sealed space; and cutting along a coating area of the heat absorbing material by using a laser.

In an exemplary embodiment, the heat absorbing material liquefies or vaporizes during being laser-cut and after being laser cut.

### BRIEF DESCRIPTION OF THE DRAWINGS

FIG. 1 is a front view of a display panel motherboard according to an exemplary embodiment of the present disclosure.

FIG. 2 is a cross-sectional view of a display panel formed by cutting the display panel motherboard of FIG. 1 in an encapsulation area.

FIG. 3 is a cross-sectional view of a display panel according to an exemplary embodiment of the present disclosure.

FIG. 4 is a flow chart of a method for manufacturing a display panel according to an exemplary embodiment of the present disclosure.

### DETAILED DESCRIPTION OF THE INVENTION

At present, during the manufacturing of the display panel, an overall process is performed on the motherboard, then a cutting and separation is implemented thereon, and the process of the back-end module is further completed. Taking a flexible display panel as an example, a plurality of flexible display panels are formed on one large substrate, that is, the display panel motherboard is obtained, which is then cut to form independent flexible display panels. Generally, the display panel motherboard is usually cut by cutter wheel or laser. Compared with the cutter wheel, laser cutting is widely used due to its high energy, good unidirectionality, high cutting efficiency, and high precision.

However, in the laser cutting process, the film and the substrate are damaged by the heat of cutting. Specifically, in order to ensure effective cutting of the flexible display substrate, certain strength of laser cutting is required, and a cutting reserved area is reserved to provide a certain range of laser radiation. If the laser cutting strength is too large, a large stress will be generated as the flexible substrate is subjected to heat, thereby causing the thin film transistor on the flexible substrate vulnerable. If the laser radiation range is too wide, the pixels in the display area will be damaged by the laser. Thus, components of the edge of the display panel are extremely easy to be damage and moisture is likely to permeate from the side of the display panel, resulting in poor encapsulating. In addition, display devices in prior art are usually encapsulated with frit layer. When the display panel in prior art is subjected to the frit layer cutting process, cracks get easy to appear on the cut end surface of the frit layer, and expansion of the microcracks will easily induce failure of the frit layer, thereby resulting in failure of the entire encapsulating process.

In order to facilitate the understanding of the present disclosure, the present disclosure will be described in details hereinafter with reference to the accompanying drawings. Preferred exemplary embodiments of the present disclosure are shown in the drawings. However, the disclosure may be embodied in various forms and is not limited to the exemplary embodiments described herein. Rather, these exemplary embodiments are provided so that the understanding of the present disclosure will be more thorough.

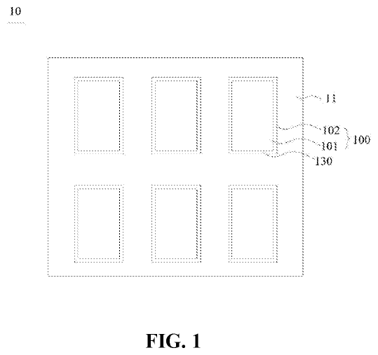

FIG. 1 shows a display panel motherboard 10 of an exemplary embodiment of the present disclosure, including a plurality of display panels 100 and a cutting reserved area 11 surrounding each of the display panels 100. It can be understood that the plurality of display panels 100 are in array distribution.

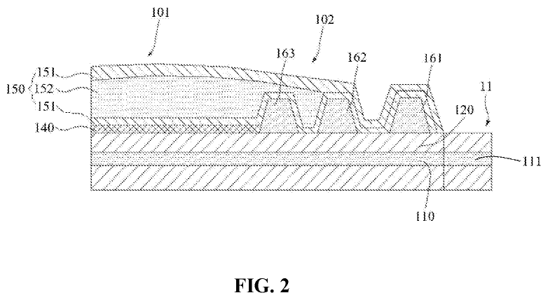

Referring to FIG. 1 and FIG. 2, at least a portion of the cutting reserved area 11 is provided with a first reflective layer 111, and the first reflective layer 111 and a source/drain of the display panel 100 are positioned on a same layer.

In the afore-mentioned display panel motherboard 10, at least a portion of the cutting reserved area 11 is provided with a first reflective layer 111. When the display panel motherboard is cut into display panels 100, the first reflective layer 111 can reflect laser energy, thereby functioning to amplify laser energy. In an actual operation, the laser energy can be appropriately reduced, as well as the laser spot, and the laser is amplified by the first reflective layer 111 to meet the cutting requirement. In this way, the risk that moisture penetrating from the side of the display panel 100 to cause poor encapsulating due to the damage to the film such as the encapsulating film because of thermal expansion is reduced, which improves encapsulation reliability and the yield rate and service life of the display panel 100.

In addition, the first reflective layer 111 is disposed in the same layer as the source/drain in the thin film transistor (TFT) array 120 of the display panel 100. The first reflective layer and the source/drain of the display area 101 can be synchronously formed without additional process, which is convenient in manufacturing.

In an exemplary embodiment, the display panel 100 further includes an encapsulation area 102. The cutting reserved area 11 surrounds the encapsulation area 102. A second reflective layer 110 is disposed in a non-display area within the encapsulation area 102. In this way, the second reflective layer 110 can further disperse heat during laser cutting, and is particularly advantageous for reducing heat entering the display area of the display panel 100 during laser cutting, thereby improving the reliability of the encapsulation.

Further, the first reflective layer 111 and the second reflective layer 110 are disposed on the same layer, which is convenient for simultaneous molding.

Further, the first reflective layer 111 is a metal reflective layer or a metal alloy reflective layer, which has a good reflection effect.

Further, the second reflective layer 110 is a metal reflective layer or a metal alloy reflective layer.

Furthermore, the first reflective layer 111 and the second reflective layer 110 have the same material. Preferably, the first reflective layer 111 and the second reflective layer 110 are both metal reflective layers.

Specifically, the first reflective layer 111 and/or the second reflective layer 110 have a multi-layer structure. Preferably, the first reflective layer 111 and/or the second reflective layer 110 have a three-layer structure.

Preferably, the first reflective layer 111 has the same material as the source/drain of the display area 101 in the display panel 100. Preferably, the second reflective layer 110 has the same material as the source/drain of the display area 101 of the display panel 100. In this way, the first reflective layer 111 and/or the second reflective layer 110 can be simultaneously formed together with the source/drain of the display area 101 by using the same material.

Further, the first reflective layer 111 and/or the second reflective layer 110 are Ti/Al/Ti laminates, or the first reflective layer 111 and/or the second reflective layer 110 are Mo/Al/Mo laminates. Taking the Ti/Al/Ti laminates as an example, the Ti/Al/Ti laminates can be obtained by sequentially forming a Ti layer, an Al layer, and a Ti layer in this order. Furthermore, the first reflective layer 111 and/or the second reflective layer 110 are Ti/Al/Ti laminates.

Specifically, the first reflective layer 111 and the second reflective layer 110 are simultaneously formed in the non-display area and the cutting reserved area 11 within the encapsulation area 102 when the source/drain of the display area 101 is formed. No additional process is needed, which is convenient in manufacturing.

That is, the source/drain located in an outer edge of the display area 101 extends into the non-display area and the cutting reserved area 11 of the encapsulation area 102 to form the first and/or second reflective layer 110. Generally, during the process of forming the TFT array 120 in the display area 101, a source/drain is formed by a process such as evaporation or sputtering. After that the source/drain of the display area 101 is patterned to obtain a desired electrode shape. For example, an etching process is used to remove unnecessary portions of the source/drain. In the present disclosure, when the source/drain is formed on the display area 101, the first reflective layer 111 and the second reflective layer 110 are obtained just by forming a similar source/drain on the non-display area and the cutting reserved area 11 of the encapsulation area 102.

It can be understood that the cutting can be performed along an encapsulation edge of the encapsulation area 102 during the cutting, thereby forming a plurality of display panels 100.

Further, a first reflective layer 111 is disposed in the cutting reserved area 11 on at least one side of the display panel 100.

The display panel 100 further includes a binding area 130. The binding area 130 is located on a side of the display panel 100. The cutting reserved area 11 provided with the first reflective layer 111 and the binding area 130 are not located on the same side of the display panel 100. That is, the first reflective layer 111 is disposed in the cut reserved area 11 without the binding area. Moreover, the side without the binding area 130 of the display panel 100, and the cutting reserved area 11 are both provided with the first reflective layer 111.

Specifically, the binding area 130 is a dense wiring area, which is usually a metal wiring part. The metal wiring part itself can reflect the laser light, therefore the binding area 130 may be provided with no second reflective layer 110. However, it can be understood that in other embodiments, the binding area 130 can also be provided with the second reflective layer 110.

In an exemplary embodiment, the display area 101 includes a pixel defining layer 140. A first dam 161 and a second dam 162 are disposed around the pixel defining layer 140 in the encapsulation area 102. The first dam 161 is located between the second dam 162 and the encapsulation edge of the encapsulation area 102. The dam can increase a distance of water oxygen permeation and prevent organic materials of the organic film formed by inkjet printing from diffusing, thereby improving encapsulation reliability. It can be understood that in other exemplary embodiments, a planarization layer (not shown) can be disposed between the TFT array 120 and the pixel defining layer 140.

Further, there is an interval between the first dam 161 and the second dam 162. The display panel 100 further includes a thin film encapsulation structure 150. The thin film encapsulation structure 150 is disposed on the display area 101 and the encapsulation area 102, and the thin film encapsulation structure 150 forms a groove at the interval.

The thin film encapsulation structure 150 includes at least two inorganic encapsulation layers 151 disposed in a stacked manner, and an organic encapsulation layer 152 disposed between adjacent two inorganic encapsulation layers 151. In this way, the inorganic encapsulation layer 151 of the thin film encapsulation structure 150 is disposed at the interval between the first dam 161 and the second dam 162 to increase adhesion of the inorganic encapsulation layer. The thin film encapsulation structure 150 forms a groove at the interval, and can further increase the distance of water oxygen permeation, thereby improving encapsulation reliability. It will be appreciated that the thin film encapsulation structure 150 is disposed on the inner side of the encapsulation edges.

The organic encapsulation layer 152 of the thin film encapsulation structure 150 is disposed on an inner side of the second dam 162. In this way, the problem of encapsulation failure due the overflow of the organic material of the organic encapsulation layer 152 can be avoided.

The encapsulation area 102 further includes a third dam 163 surrounding the pixel defining layer 140. The third dam 163 is disposed on an inner side of the second dam 162 and spaced apart from the second dam 162, which further improves the encapsulation reliability.

A display panel 100 is further provided in an exemplary embodiment of the present disclosure, which is formed by cutting the afore-described display panel motherboard 10.

The display panel 100 includes a display area 101 and an encapsulation area 102 surrounding an outer circumference of the display area 101. The encapsulation area 102 has a second reflective layer 110 therein, and the second reflective layer 110 is a source/drain.

Further, the source/drain at an outer edge of the display area 101 extends into the encapsulation area 102 to form the second reflective layer 110.

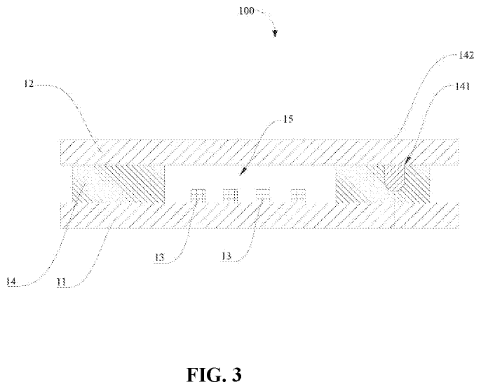

Further, referring to FIG. 3, which is a cross-sectional view of the display panel 100 according to an exemplary embodiment of the present disclosure. In this exemplary embodiment, the display panel 100 further includes a substrate 11, a cover plate 12 disposed opposite the substrate 11, and an encapsulation layer 14 bonding the substrate 11 and the cover plate. The display panel 100 is used for encapsulating a display device to isolate the display device from external environment, so that the organic layer material sensitive to moisture and oxygen in the display device can be kept in a closed environment to ensure the service life of the display device.

In this exemplary embodiment, the display device is an OLED display device, and the display panel 100 is used to enable encapsulating of an OLED screen of a mobile phone. It can be understood that in other embodiments, the display device can also be other types of display devices such as an LCD, and the display panel 100 is not limited to be used for encapsulation of a mobile phone OLED screen. In other embodiments, the display panel 100 can also be used to encapsulate and process screens of other electronic products such as tablets and notebooks.

In this exemplary embodiment, the display panel 100 includes a substrate 11, a cover plate 12, a display device 13, and an encapsulation layer 14. The substrate 11 is disposed substantially parallel to the cover plate 12, and the encapsulation layer 14 is sandwiched between the substrate 11 and the cover plate 12. The encapsulation layer 14 forms a sealed space 15 together with the substrate 11 and the cover plate 12, and the display device 13 is disposed on the substrate 11 and accommodated in the sealed space 15, thereby separating the display device 13 from the external environment.

The substrate 11 and the cover plate 12 have a substantially rectangular structure, and the substrate 11 and the cover plate 12 can be selectively chamfered or rounded. Portions of the substrate 11 and the cover plate 12 are in contact with the encapsulation layer 14. Central portions of the substrate 11 and the cover plate 12 that are not in contact with the encapsulation layer 14 are fitted to the encapsulation layer 14 to enclose a sealed space 15.

A first contact film (not shown) can be disposed on a surface of the substrate 11 in contact with the encapsulation layer 14. The first contact film is used to facilitate an insulating effect of the substrate 11 and the encapsulation layer 14 against outside moisture and oxygen.

A second contact film (not shown) can be disposed on a surface of the cover plate 12 in contact with the encapsulation layer 14. The second contact film is used to facilitate an insulation effect of the cover plate 12 and the encapsulation layer 14 against outside moisture and oxygen. A water-oxygen channel is formed between the second contact film and the encapsulation layer 14 to extend a path on which the outside moisture and oxygen enter the sealed space 15 through the water oxygen channel. The insulating effect of the cover plate 12 and the encapsulation layer 14 against the outside moisture and oxygen is enhanced by the principle of the labyrinth seal.

In other embodiments, the first contact film can be omitted if the insulating effect of the substrate 11 and the encapsulation layer 14 against the outside moisture and oxygen is not considered to be facilitated; if the insulating effect of the cover plate 12 and the encapsulation layer 14 against the outside moisture and oxygen is not considered to be facilitated, the second contact film layer can also be omitted.

In this exemplary embodiment, the substrate 11 and the cover plate 12 are both made of glass material.

The encapsulation layer 14 has a substantially rectangular structure and can be selectively chamfered or rounded. One end of the encapsulation layer 14 is connected to the substrate 11, and the other end thereof is connected to the cover plate 12. The encapsulation layer 14 is substantially annular.

In this exemplary embodiment, the encapsulation layer 14 is formed by enclosing of four mutually perpendicular bezels, and the encapsulation layer 14 has a substantially square ring shape. It can be understood that in other embodiments, the encapsulation layer 14 can also be a circular ring, an elliptical ring or the like in other forms, as long as the encapsulation layer 14 can be closed end to end.

The encapsulation layer 14 includes a glass frit, and the glass frit can be selected from one or more of V₂O₅, P₂O₅, BaO, SiO₂, B₂O₃, Al₂O₃, SnO, TeO₂, MgO, CaO, ZnO, TiO₂, WO₃, Bi₂O₃, Fe₂O₃, CuO, Sb₂O₃, Ru₂O, Rb₂O, phosphoric acid tin glass, vanadate glass, and borosilicate.

When the encapsulation is performed, the substrate 11 and the cover plate 12 are pressed together, so that the encapsulation layer 14, the substrate 11, and the cover plate 12 are bonded to each other. Scanning is performed by using the laser along the encapsulation layer 14, and the laser beam travels through the cover plate 12 to reach the encapsulation layer 14. The glass frit in the encapsulation layer 14 absorbs the high energy of the laser beam and melts, so that the encapsulation layer 14 is closely bonded to the substrate 11 and the cover plate 12, thereby realizing an encapsulating process for the display device.

According to the display panel 100 provided in the exemplary embodiment of the present disclosure, in order to improve the yield rate of the encapsulation, and provide better protection for the display device 13, the encapsulation layer 14 in the display panel 100 is provided with a groove 141. The groove 141 is disposed on a surface of the encapsulation layer 14 in an enclosing direction of the encapsulation layer 14. A thickness of the groove 141 is less than a thickness of the encapsulation layer 14. The groove 141 is located below a cutting line 142. The groove 141 is provided with a heat absorbing material for absorbing heat generated during the laser processing.

In this exemplary embodiment, a melting point of the heat absorbing material is lower than a melting point of the encapsulation layer 14. Preferably, the heat absorbing material is made of thermal grease, and the heat absorbing material has a good thermal conductivity when it is made of thermal grease. The thermal grease vaporizes from a grease state at a temperature of 230° C. and takes away the heat generated by the laser beam processing. It can be understood that in other embodiments, instead of the thermal grease, the heat absorbing material can also use other materials, as long as the heat absorbing material can liquefy or vaporize at a suitable temperature and can take away the heat generated by the laser beam processing.

In this exemplary embodiment, the heat absorbing material is completely filled with the groove 141 to increase an overall heat absorption amount of the heat absorbing material. In other embodiments, the heat absorbing material can also be partially filled in the groove 141 to reduce a manufacturing cost of the module encapsulation.

In this exemplary embodiment, a cross section of the groove 141 in the direction perpendicular to the cover plate 12 is a curved surface. It can be understood that in other embodiments, the groove 141 can be other shapes as long as the groove 141 can accommodate the heat absorbing material.

Preferably, a width of the groove 141 is one-third to one-half of a width of the encapsulation layer 14, and the groove 141 is disposed adjacent to the outer circumference of the annular encapsulation layer 14.

In this way, an outer portion of the encapsulation layer 14 can be better supported, and the outer portion of the encapsulation layer 14 can maintain a better connection strength during the cutting process. Therefore, the outer portion of the encapsulation layer 14 can be prevented from being entirely broken during the cutting process.

During the encapsulation, a high energy laser beam radiates the encapsulation layer 14, and the encapsulation layer 14 is melted under high energy and high temperature laser radiation, so that the encapsulation layer 14 can be bonded to the substrate 11 and the cover plate 12. Due to the groove 141, when the cutting tool cuts the portion of the encapsulation layer 14 to compress the cutting allowance, and implement a narrow bezel design, the groove 141 becomes a remaining path of the cutting tool processing, and an area of a machining section of the tool and the encapsulation layer 14 is reduced. The reduction also reduces the number of microcracks caused by the cutting process of the cutting tool and improves the cutting effect of the encapsulation layer 14.

When the groove 141 is accommodated with the heat absorbing material, the heat absorbing material accommodated in the groove 141 can absorb the heat of the laser beam, and the heat absorbing material vaporizes under the irradiation of the laser beam, takes away part of the heat of the laser beam, and reduces the temperature of the encapsulation layer 14 at the time of encapsulating. Therefore, the first contact film and the second contact film which are in direct contact with the encapsulation layer 14 can have a relatively low temperature when the encapsulation layer 14 is in encapsulating. In this way, the first contact film and the second contact film are protected by preventing the first contact film layer and the second contact film layer from being damaged by high temperature.

If the protection of the first contact film layer and the second contact film layer is not considered, the heat absorbing material filled in the groove 141 can also be omitted.

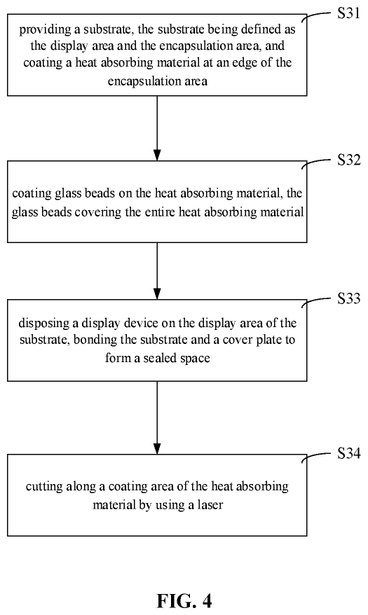

A method for encapsulating is further provided in the present disclosure, which can ensure the encapsulation effect and the encapsulation yield rate while compressing the cutting allowance to implement the narrow bezel design. Referring to FIG. 4, FIG. 4 is a flowchart of a method for encapsulating according to an exemplary embodiment of the present disclosure. The method for encapsulating includes:

S31: providing a substrate, the substrate being defined as the display area 101 and the encapsulation area 102, and coating a heat absorbing material at an edge of the encapsulation area 102. The heat absorbing material may be a solid heat absorbing material.

S32: coating glass beads on the heat absorbing material, the glass beads covering the entire heat absorbing material;

S33: disposing a display device on the display area 101 of the substrate, bonding the substrate and a cover plate to form a sealed space;

S34: cutting along a coating area of the heat absorbing material by using a laser.

Since an avoidance space is provided in a frit layer, the cutting tool can cut off the frit layer relatively easily, thereby compressing the cutting allowance and implementing the narrow bezel design. At this moment, the avoidance space becomes a reserved channel for the processing of the cutting tool, so that the area of the processed section of the cutting tool and the frit layer is reduced, which reduces the number of microcracks caused by the cutting process and improves the cutting effect of the frit layer.

Due to the addition of the heat absorbing material, which liquefies or vaporizes during laser cutting and after laser cutting, the glass cover plate and the glass substrate can be better protected, thus resulting in a better encapsulating effect.

A display device (not shown) is further provided in the present disclosure, which includes the afore-described display panel 100.

The display panel 100 provided in the present disclosure has a groove 141 formed in the encapsulation layer 14, so that the cutting tool does not contact a side wall of the groove 141 when cutting the encapsulation layer 14. In this way, an end surface contact area is reduced when the cutting tool processes the encapsulation layer 14, thereby compressing the cutting allowance to implementing a narrow bezel design while reducing the crack problem and ensuring the encapsulating effect and the yield rate of the encapsulation.

A display terminal is further provided in the present disclosure, which includes the afore-described display panel 100.

The display terminal can be a device such as a mobile phone, a television or a tablet.

Technical features of the forgoing exemplary embodiments may be arbitrarily combined. For brief description, not all possible combinations of the technical features in the above exemplary embodiments are described. However, as long as combinations of the technical features are not contradicted, the combinations should be considered as belonging to the scope of this disclosure.

The forgoing exemplary embodiments are merely illustrative of several embodiments of the present disclosure, and the description thereof is not to be construed as limiting. It should be noted that a number of variations and modifications may be made by those skilled in the art without departing from the spirit and scope of the present disclosure. Therefore, the scope of protection of the disclosure should be determined by the appended claims.

1. A display panel motherboard comprising:
a plurality of display panels; and
a cutting reserved area surrounding each of the display panels;
wherein at least a portion of the cutting reserved area is provided with a first reflective layer, and the first reflective layer and a source/drain of the display panel are positioned on a same layer.

2. The display panel motherboard according to claim 1, wherein the cutting reserved area is at least located on one side of the display panel, and the first reflective layer is disposed in the cutting reserved area.

3. The display panel motherboard according to claim 1, wherein the display panel comprises a binding area, the binding area being located on one side of the display panel; and the cutting reserved area provided with the first reflective layer and the binding area is located on different sides of the display panel.

4. The display panel motherboard according to claim 3, wherein a side surface of the display panel without the binding area and the cutting reserved area are provided with the first reflective layer.

5. The display panel motherboard according to claim 1, wherein the first reflective layer comprises a metal reflective layer or a metal alloy reflective layer.

6. The display panel motherboard according to claim 1, wherein the first reflective layer has a multi-layer structure, and the first reflective layer is a Ti/Al/Ti laminates or a Mo/Al/Mo laminates.

7. The display panel motherboard according to claim 1, wherein the display panel further comprises an encapsulation area, the cutting reserved area surrounds the encapsulation area, and a non-display area in the encapsulation area is provided with a second reflective layer.

8. The display panel motherboard according to claim 7, wherein the first reflective layer and the second reflective layer are disposed on a same layer.

9. The display panel motherboard according to claim 8, wherein the first reflective layer and the second reflective layer are both metal reflective layers.

10. The display panel motherboard according to claim 1, wherein the display panel comprises a thin film encapsulation structure, the thin film encapsulation structure is disposed on the display area and the encapsulation area, and the thin film encapsulation structure has a groove defined at an interval.

11. The display panel motherboard according to claim 10, wherein the display area is provided with a pixel defining layer, and the encapsulation area is provided with a first dam and a second dam, the first dam and the second dam surround the pixel defining layer, the thin film encapsulation structure comprises at least two inorganic encapsulation layers disposed in a stacked manner, and an organic encapsulation layer disposed between two adjacent inorganic encapsulation layers, the inorganic encapsulation layer in the thin film encapsulation structure is disposed on an interval between the first dam and the second dam.

12. A display panel, formed by cutting a display panel motherboard according to claim 1, the display panel comprising:
a display area; and
an encapsulation area, the encapsulation area surrounding an outer circumference of the display area, and having a second reflective layer disposed in the encapsulation area.

13. The display panel according to claim 12, further comprising:
a substrate; and
a cover plate disposed opposite to the substrate;
wherein the encapsulation area is formed by an encapsulation layer, the encapsulation layer bonds the substrate and the cover plate;
the substrate, the encapsulation layer, and the cover plate enclose a sealed space disposing a display device, and the encapsulation layer is provided with a groove, the groove opening faces or faces away from the cover plate, and the groove is filled with heat absorbing material.

14. The display panel according to claim 13, wherein the groove is opened on a surface of the encapsulation layer along an enclosing direction of the encapsulation layer.

15. The display panel according to claim 13, wherein the encapsulation layer is annular, and the groove is disposed adjacent to an outer edge of the encapsulation layer.

16. The display panel according to claim 13, wherein a thickness of the groove is less than a thickness of the encapsulation layer.

17. The display panel according to claim 13, wherein a width of the groove is one-third to one-half of a width of the encapsulation layer.

18. The display panel according to claim 13, wherein a cross section of the groove along a direction perpendicular to the cover plate is a curved surface.

19. A method of manufacturing a display panel, comprising:
providing a substrate;
defining a display area and an encapsulation area on the substrate;
coating a heat absorbing material at an edge of the encapsulation area;
coating glass beads on the heat absorbing material, the glass beads covering the entire heat absorbing material;
disposing a display device on the display area of the substrate, and bonding the substrate and a cover plate to form a sealed space; and
cutting along a coating area of the heat absorbing material by using a laser.

20. The method for manufacturing a display panel according to claim 19, wherein the heat absorbing material liquefies or vaporizes during being laser-cut and after being laser-cut.
